(19) United States
(12) Patent Application Publication
(10) Pub. No.: US 2011/0063050 A1
(43) Pub. Date: Mar. 17, 2011

(54) SEMICONDUCTOR INTEGRATED CIRCUIT

(75) Inventor: Mitsuyuki Ashida, Kanagawa-ken (JP)

(73) Assignee: KABUSHIKI KAISHA TOSHIBA, Tokyo (JP)

(21) Appl. No.: 12/881,446

(22) Filed: Sep. 14, 2010

(30) Foreign Application Priority Data
Sep. 16, 2009 (JP) 2009-213986

(51) Int. Cl. H03H 7/01

(52) U.S. Cl. 333/174; 333/175

(57) ABSTRACT

Embodiments described a semiconductor integrated circuit includes: a first coil and a second coil which have a mutual coupling and are connected in parallel to each other; a third coil connected in series to the first coil and the second coil; a first capacitor connected in parallel to the first coil; a second capacitor connected in parallel to the second coil; a first input terminal connected to an end of the first coil and an end of the first capacitor; a second input terminal connected to an end of the second coil and an end of the second capacitor; and an input-signal supplying portion configured to supply input signals of opposite phases to the first input terminal and the second input terminal, respectively.

### CROSS-REFERENCE TO RELATED APPLICATIONS

This application is based upon and claims the benefit of priority from Japanese Patent Application No. P2009-213986, filed on Sep. 16, 2009; the entire contents of which are incorporated herein by reference.

### FIELD

Embodiments described herein relate generally to a semiconductor integrated circuit to switch the frequency band of an amplifier.

### BACKGROUND

In recent wireless communication systems for mobile terminals and the like, transmission and reception systems have come to use broader frequency bands and multiple frequency bands to support all sorts of communication systems, such as GSM, GPS, and WCDMA.

In a wireless communication system using a frequency band that is not very broad, such as several hundreds of megahertz, if the input and the output have broadband properties, intermodulation caused by in-band and out-of-band interferences or the like sometimes cause distortion components within a desired frequency band.

Accordingly, in a system of a narrow frequency band, it is desirable to narrow down the frequency band, that is, to switch the frequency band from one to another, in order to reduce the degradation of the distortion characteristics, the noise characteristics, and the like.

A wireless communication system includes a resonant circuit. The resonant circuit includes an inductor and a capacitor, and the resonant frequency of the resonant circuit is expressed as 1/{2pv(LC)}, where L is the inductance (induction coefficient) of the inductor, and C is the capacitance of the capacitor. By changing the inductance or the capacitance, the resonant frequency can be varied, that is, the frequency band can be switched from one to another.

In general, a widely-used method of varying the resonant frequency is a frequency tuning method using a passive element such as a resistor.

At high frequencies, in particular, a method using inductors or capacitors as the loads on an amplifier is used, such as a method 1 of switching the capacitance in accordance with the frequency band, a method 2 of switching the inductance similarly, or a method 3 of switching the inductance with use of the coupling coefficient of the inductors.

However, since the method 1 switches the capacitance, obtaining a broad, variable frequency range requires so a large capacitance that it is difficult to get a high Q-factor at low frequencies. Here, the Q-factor refers to a value expressed as Q=1/Rv(L/C), where R is the parasitic resistance of the inductor, L is the inductance of the coil, and C is the capacitance of the capacitor. The higher the Q-factor is, the steeper the frequency characteristics become and the more highly selective the frequency becomes.

In the method 2, the value of the inductor itself is changed by use of a switch, so that the inductors have to be provided in a number corresponding to the systems to which the method is applied, and therefore occupy a larger area. In addition, if a broader variable frequency range is desired, larger inductors are required, so that the parasitic resistance becomes larger and the Q-factor is degraded.

In the method 3, by switching between the same-phase mode and the differential mode, the inductance is varied within a range from (1−k)L to (1+k)L in accordance with the coupling coefficient k, and therefore the frequency range can be varied in accordance with the inductance. However, the resonant frequency in the same-phase mode, when the Q-factor is so low as (1/R)v{(1−k)L/C}, is higher than the resonant frequency in the differential mode. In particular, at higher frequencies, in comparison to lower frequencies, it is inherently difficult to obtain favorable characteristics, and the Q-factor of the inductor used instead of the load or the degeneration resistor has a great influence on the gain characteristics, maximum output electric power, oscillation amplitude, and the like in an analogue circuit block, such as a low noise amplifier (LNA), a power amplifier (PA), or a voltage-controlled oscillator (VCO). For those reasons, an element that has as high a Q-factor as possible is preferably used, but the method 3 has a problem that, at higher frequencies, the Q-factor is degenerated and thus desirable gain and noise characteristics cannot be achieved.

### BRIEF DESCRIPTION OF THE DRAWINGS

FIG. 1 is a system block diagram of a semiconductor integrated circuit of the invention.

FIG. 2 is a circuit diagram of Embodiment 1.

FIG. 3 is a circuit diagram of Embodiment 2.

FIG. 4 is a circuit diagram of Embodiment 3.

FIG. 5 is a circuit diagram of Embodiment 4.

FIG. 6 is a circuit diagram of Embodiment 5.

FIG. 7 is a circuit diagram of Embodiment 6.

FIG. 8 is a circuit diagram of Embodiment 7.

FIG. 9 is a circuit diagram of Embodiment 8.

### DETAILED DESCRIPTION

In general, according to one embodiment, a semiconductor integrated circuit including: a first coil and a second coil having a first coupling coefficient and being connected in parallel to each other; a third coil connected in series to the first coil and the second coil; a first capacitor connected in parallel to an end of the first coil and to an end of the third coil; a second capacitor connected in parallel to an end of the second coil and to the end of the third coil; a first input terminal connected to the end of the first coil and to an end of the first capacitor; a second input terminal connected to the end of the second coil and to an end of the second capacitor; and an input-signal supplying portion configured to supply input signals of opposite phases to the first input terminal and the second input terminal, respectively.

Some embodiments of the invention will be described below by referring to the drawings.

### Embodiment 1

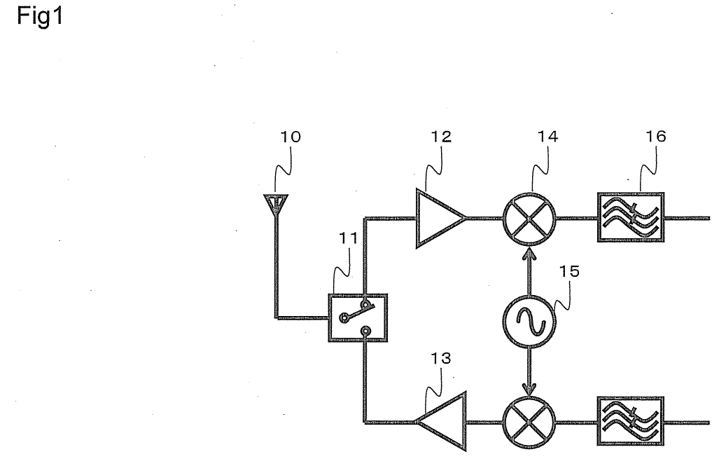

FIG. 1 is a system block diagram of a semiconductor integrated circuit of the invention. The semiconductor integrated circuit of the invention includes an antenna 10 configured to transmit and receive data, a T/R switching portion 11 configured to switch the transmission and the reception of data, a low noise amplifier (LNA) 12, a power amplifier (PA) 13, a mixer (MIX) 14, a voltage controlled oscillator (VCO) 15, and a low-pass filter (LPF) 16, and what is characteristic of the semiconductor integrated circuit of the invention is in the LNA 12 and the PA 13, in particular.

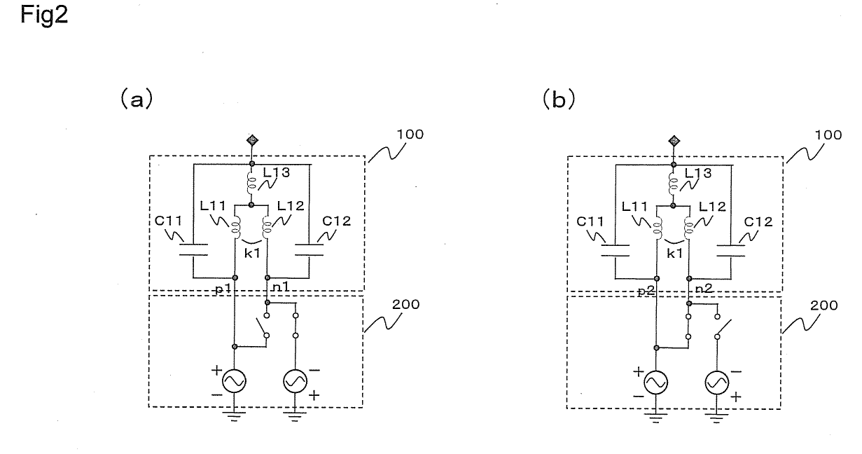

FIGS. 2A and 2B each show a resonant circuit portion 100 of the semiconductor integrated circuit according to Embodiment 1 of the invention, and the resonant circuit portion 100 is included in the LNA 12 (or in the PA 13) shown in FIG. 1. The resonant circuit portion 100 shown in FIG. 2A includes: a coil L11 with an inductance L₁ and a coil L12 with an inductance L₁ which have a coupling coefficient k1 and are connected in parallel to each other; a coil L13 with an inductance L₂ connected in series to both the coil L11 and the coil L12; a capacitor C11 with a capacitance C₁ connected in parallel with the coil L11; and a capacitor C12 with a capacitance C₁ connected in parallel with the coil L12.

An input terminal p1 is connected both to one end of the coil L11 and to one end of the capacitor C11, and an input terminal n1 is connected both to one end of the coil L12 and to one end of the capacitor C12. Signals are supplied both to the input terminal p1 and to the input terminal n1 from an input-signal supplying portion 200.

The coil L11 and the coil L12 are wound in such directions that their respective magnetic fluxes reinforce each other when signals of opposite phases to each other pass through the coil L11 and the coil L12, respectively.

When the input-signal supplying portion 200 supplies signals of opposite phases to the input terminal p1 and to the input terminal n1, respectively, signals of opposite phases respectively pass through the coil L11 and the coil L12 that form the inductor, so that a magnetic force acts to make the magnetic fluxes reinforce each other. Accordingly, the inductance L_{L} of the inductor including the coils L11, L12, and L13 is expressed as L_{L}=L₁(1+k₁), where k₁ is the coupling coefficient of the coils L11 and L12. In addition, since the signal that passes through the coil L12 has the opposite phase, the influence of the coil L13 is negligible. Accordingly, the resonant frequency f_{L}=1/R{(2pv(L_{L}×C₁))}, and the Q-factor Q_{L}=(1/R)v(L_{L}/C₁), so that the resonant circuit portion 100 can be made to resonate at low frequencies without degrading the Q-factor. Note that R in the equations above is the parasitic resistance of the corresponding inductor (R means the same in the following descriptions).

The resonant circuit portion 100 shown in FIG. 2B is the same as the one shown in FIG. 2A except the phase of the signal to be supplied to the input terminal n1. In FIG. 2B, signals of the same phase are supplied to the input terminal n2 and the input terminal p2 from the input-signal supplying portion 200. When signals of the same phase are supplied to the input terminals p2 and n2, signals of the same phase respectively pass through the coil L21 and the coil L22 that form the inductor, so that a magnetic force acts to make the magnetic fluxes cancel each other out. Accordingly, the inductance of the inductor including the coils L21 and L22 is expressed by L₁(1−k₁), where k₁ is the coupling coefficient of the coils L21 and L22. In addition, since the signal that passes through the coil L21 is a signal of the same phase, the inductance L_{H} of the inductor including the coils L21, L22, and L23 is expressed as L_{H}=2L₂+L₁(1−k₁). In addition, the resonant frequency f_{H}=1/{2pv(L_{H}C₁)} and the Q-factor Q_{H}=(1/R)v(L_{H}/C₁). Accordingly, while sufficient isolation is secured, the frequency can be set to a desired one. In addition, because the Q-factor in the high-frequency operation mode can be improved, favorable gain characteristics and noise characteristics can be obtained. Specifically, while the Q factor of the coils L11 and L12 and the Q-factor of the coils L21 and L22 are degraded by the same-phase mode, each of the degraded Q-factors can be compensated by the coil L13/L23, so that a high Q-factor can be secured even in the high-frequency mode, and favorable gain characteristics and noise characteristics can be obtained.

### Embodiment 2

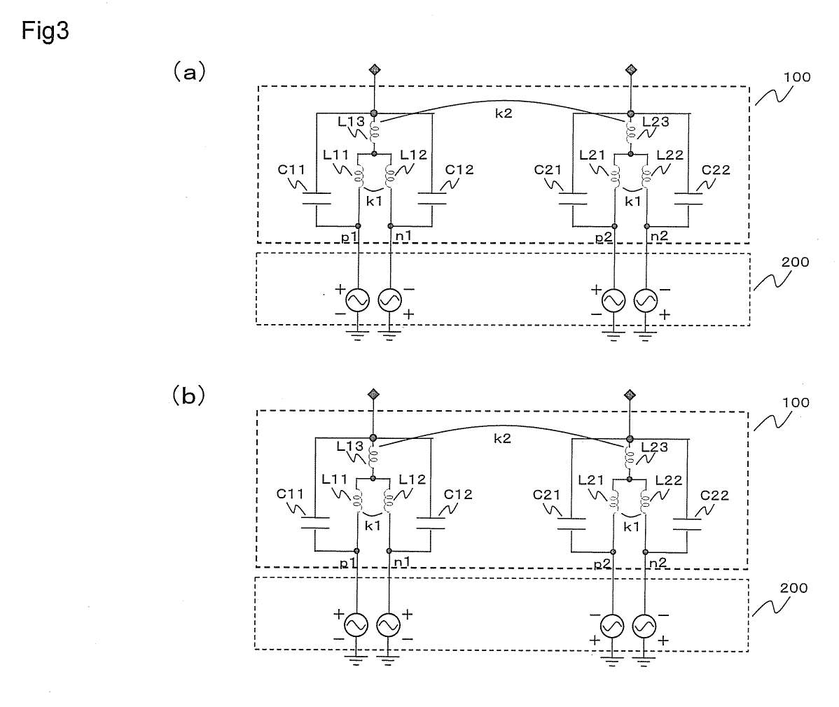

FIG. 3 shows a resonant circuit portion 100 of a semiconductor integrated circuit according to Embodiment 2 of the invention. The resonant circuit portion 100 shown in FIG. 3A includes: a coil L11 with an inductance L₁ and a coil L12 with an inductance L₁ which have a coupling coefficient k1 and are connected in parallel to each other; a coil L21 with an inductance L₁ and a coil L22 with an inductance L₁ which have also a coupling coefficient k1 and are connected in parallel to each other; a coil L13 with an inductance L₂ which is connected in series both to the coil L11 and to the coil L12; a coil L23 with an inductance L₂, which is connected in series both to the coil L21 and to the coil L22; a capacitor C11 with a capacitance C₁ which is connected in parallel to the coil L11; a capacitor C12 with a capacitance C₁ which is connected in parallel to the coil L12; a capacitor C21 with a capacitance C₁ which is connected in parallel to the coil L21; and a capacitor C22 with a capacitance C₁ which is connected in parallel to the coil L22.

Note that the coil L13 and the coil L23 have a coupling coefficient k₂.

The coil L11 and the coil L12 are wound in such directions that their respective magnetic fluxes reinforce each other when signals of opposite phases pass through the coils L11 and L12, respectively. In addition, the coil L21 and the coil L22 as well as the coil L13 and the coil L23 are wound in the same manner.

An input terminal p1 is connected both to one end of the coil L11 and to one end of the capacitor C11, and an input terminal n1 is connected both to one end of the coil L12 and to one end of the capacitor C12. Moreover, an input terminal p2 is connected both to one end of the coil L21 and to one end of the capacitor C21, and an input terminal n2 is connected both to one end of the coil L22 and to one end of the capacitor C22. Signals are supplied to all the input terminals p1, n1, p2, and n2 from an input-signal supplying portion 200.

When signals of opposite phases are supplied respectively to the input terminal p1 and to the input terminal n1, signals of opposite phases respectively pass through the coil L11 and the coil L12 forming the inductor, so that a magnetic force acts to make the magnetic fluxes reinforce each other. Accordingly, the inductance L_{L} of the inductor including the coils L11, L12, and L13 is expressed as L_{L}=L₁(1+k₁), where k₁ is the coupling coefficient of the coils L11 and L12. Likewise, the inductance L_{L} of the inductor including the coils L21 and L22 is expressed as L_{L}=L₁(1+k₁), where k₁ is the coupling coefficient of the coils L21 and L22.

In addition, since the signal that passes through each of the coils L12 and L22 has the opposite phase, the influence of each of the coils L13 and L23 is negligible. Accordingly, the resonant frequency f_{L}=1/R{(2pv(L_{L}×C₁))}, and the Q-factor Q_{L}=(1/R)v(L₁/C₁), so that the resonant circuit portion 100 can be made to resonate at low frequencies without degrading the Q-factor.

The resonant circuit portion 100 shown in FIG. 3B is the same as the one shown in FIG. 3A except the phases of the signals to be supplied to the input terminal n1 and p2. In FIG. 3B, signals of the same phase are supplied to the input terminals p1 and n1, and signals of the same phase are supplied to the input terminals p2 and n2. Signals to be input into the respective input terminals p1 and p2 have opposite phases, and signals to be input into the respective input terminals n1 and n2 have opposite phases.

When signals of the same phase are supplied to the input terminals p1 and n1, signals of the same phase pass through the coil L11 and the coil L12, so that a magnetic force acts to make the magnetic fluxes cancel each other out. In addition, when signals of the same phase are supplied to the input terminals p2 and n2, signals of the same phase pass through the coil L21 and the coil L22, so that a magnetic force acts to make the magnetic fluxes cancel each other out. Accordingly, the inductance of the inductor including the coils L11 and L12 is expressed by L₁(1−k₁), where k₁ is the coupling coefficient of the coils L11 and L12. Likewise, the inductance of the inductor including the coils L21 and L22 is expressed by L₁(1−k₁), where k₁ is the coupling coefficient of the coils L21 and L22.

In addition, since signals of opposite phases respectively pass through the coil L13 and the coil L23, so that a magnetic force acts to make the magnetic fluxes reinforce each other. Accordingly, the inductance of the inductor including the coils L13 and L23 is expressed by L₂(1+k₂), where k₂ is the coupling coefficient of the coils L13 and L23.

Accordingly, the inductance L_{H} of the inductor including the coils L11, L12, and L13 is expressed as L_{H}=2L₂(1+k₂)+L₁(1−k₁). In addition, the resonant frequency f_{H}=1/{2pv(L_{H}C)}, and the Q-factor Q_{H}=(1/R)v(L_{H}/C), so that the resonant circuit portion 100 can be made to resonate at high frequencies without degrading the Q-factor.

Note that, if the coils L13 and L23 having a coupling coefficient k₂ are not provided, the inductance L_{H}′ of such a case is expressed as L₁(1−k₁), which means that the Q-factor of this Embodiment 2 is v(L_{H}/L_{H}′) times higher than the Q-factor of this case. Accordingly, the resonant circuit portion 100 can be made to resonate at high frequencies without degrading the Q-factor.

### Embodiment 3

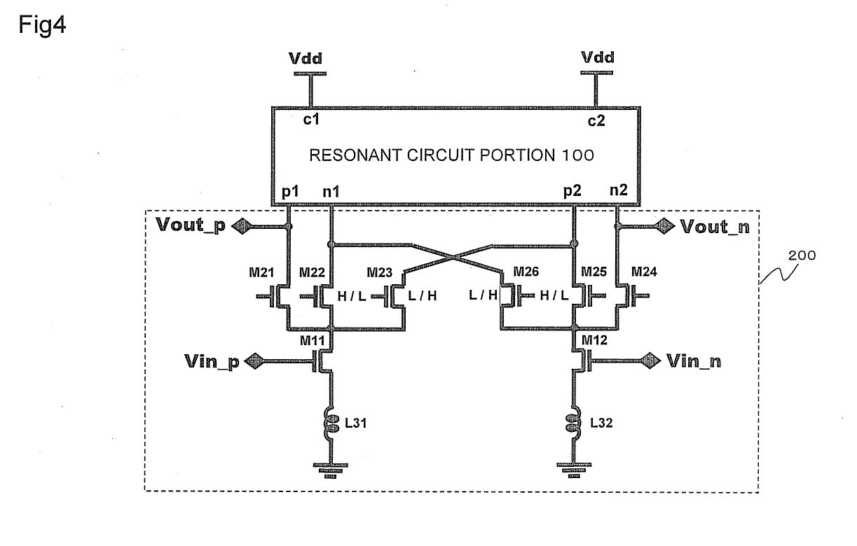

FIG. 4 shows a semiconductor integrated circuit according to Embodiment 3 of the invention. Embodiment 3 is a differential amplifier circuit of a cascade configuration including the resonant circuit portion 100 of Embodiment 2 and an input-signal supplying portion 200 including switches M21 to M26 configured to selectively switch signals to supply either signals of the same phase or signals of opposite phases to the coils L11 and L12, respectively, and to the coils L21 and L22, respectively.

To resonate the resonant circuit portion 100 at low frequencies, signals of opposite phases are supplied to the resonator by turning the switches M21, M23, M24, and M26 ON (H), and by turning the switches M22 and M25 OFF (L).

As in Embodiment 2, the inductance L_{L}, the resonant frequency f_{L}, and the Q-factor Q_{L} are expressed as L_{L}=L₁ (1+k₁), f_{L}=1/{2pv(L_{L}C)}, and Q_{L}=(1/R)v(L_{L}/C), respectively.

To resonate the resonant circuit portion 100 at high frequencies, signals of the same phase are supplied to the resonator by turning the switches M21, M22, M24, and M25 ON (H), and by turning the switches M23 and M26 OFF (L).

As in Embodiment 2, the inductance L_{H}, the resonant frequency f_{H}, and the Q-factor Q_{H} are expressed as L_{H}=2L₂(1+k₂)+L₁(1−k₁), f_{H}=1/{2pv(L_{H}C)}, and Q_{H}=(1/R)v(L_{H}/C), respectively.

Accordingly, besides the effects obtained by Embodiment 2, Embodiment 3 can switch selectively the signals to supply either signals of the same phase or signals of opposite phases to the respective coils.

### Embodiment 4

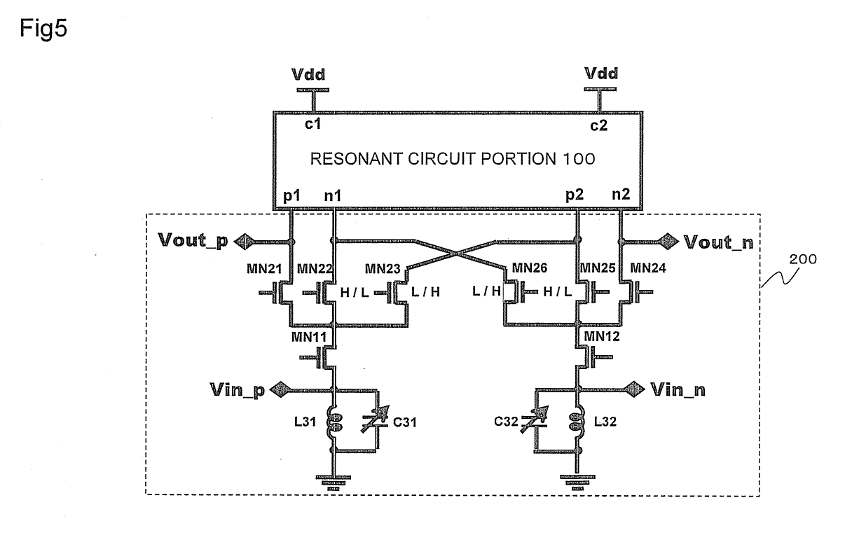

FIG. 5 shows a circuit of Embodiment 4 of the invention. In the circuit of Embodiment 4, an LC resonant circuit is provided in the input-signal supplying portion 200 of Embodiment 3 by further providing a variable capacitance capacitor C31 in parallel to the coil L31 and a variable capacitance capacitor C32 in parallel to the coil L32.

By changing the capacitance of the switched-capacitor C31 and the capacitance of the switched-capacitor C32, not only the effects obtained in Embodiments 1 to 3 but also an additional effect can be obtained. Specifically, the operation mode can be switched, when necessary, between the high-frequency operation mode and the low-frequency operation mode. Note that the impedance of the LC resonant circuit is made sufficiently high at desired operation frequencies.

### Embodiment 5

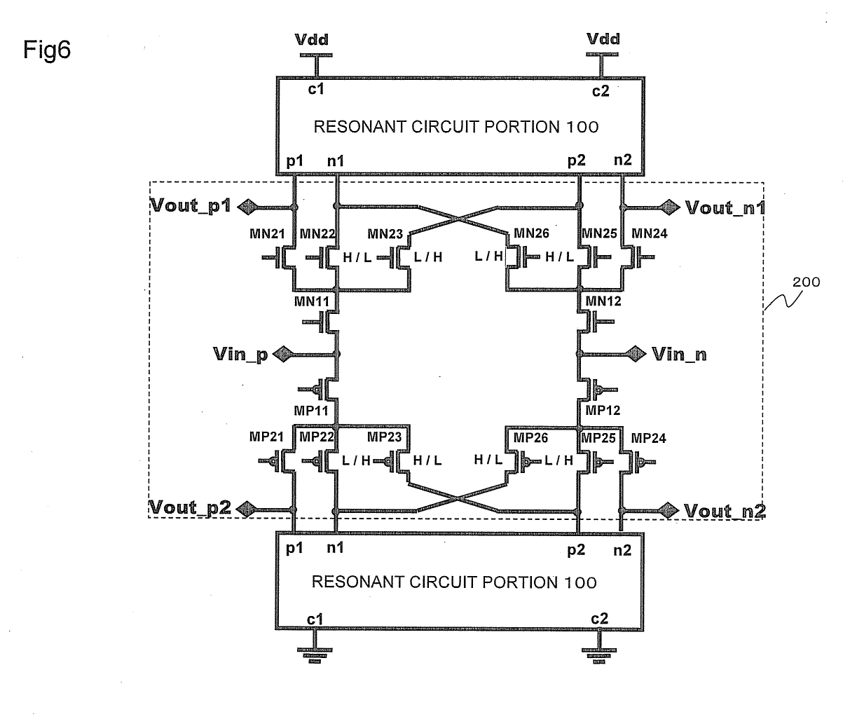

FIG. 6 shows a circuit of Embodiment 5 of the invention. The circuit of Embodiment 5 is a complementary cascade-connected gate-grounded differential amplifier circuit including: two resonant circuits each being the resonant circuit 100 of Embodiment 2; and an input-signal supplying portion 200 including switches MN21 to MN26 and MP21 to MP26 configured to selectively switch signals to supply either signals of the same phase or signals of opposite phases to the coils L11 and L12, respectively, and to the coils L21 and L22, respectively. The resonant circuit portion 100 of Embodiment 5 is controlled in the same way as in the case of Embodiment 3, and the control signals to control the switches MP21 to MP26 are the reverse signals of the control signals for the switches MN21 to MN26. An output signal VOUT_P1 and an output signal VOUT_P2 are signals of the same phase, so that these output signals are output by summing the currents.

### Embodiment 6

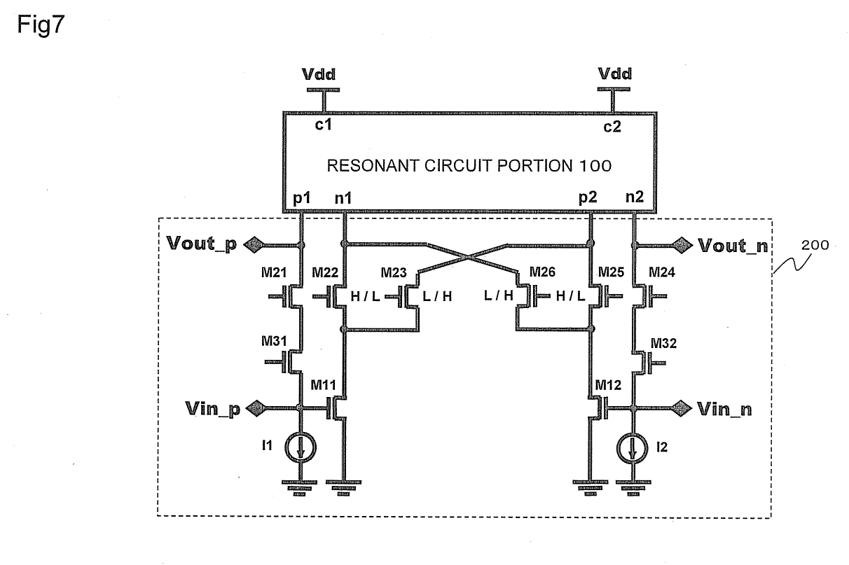

FIG. 7 shows a circuit of Embodiment 6 of the invention. The circuit of Embodiment 6 is an amplifier circuit including: a resonant circuit portion 100 that is similar to the one in Embodiment 2; and an input-signal supplying portion 200 including switches M21 to M26 and M31 and M32 configured to selectively switch signals to supply either signals of the same phase or signals of opposite phases to the coils L11 and L12, respectively, and to the coils L21 and L22, respectively. While the switches M11 and M12 operate as a common-source amplifier, the switches M31 and M32 operate as a common-gate amplifier. The common-source circuit and the common-gate circuit are an inverting amplifier and a noninverting amplifier, respectively, so that, if the transconductance of the switches M11 and M12, and the transconductance of the switches M31 and M32 are made to be the same transconductance Gm, signals with the same amplitude and opposite phases pass through the resonant circuit portion 100. In addition, DC current sources I1 and I2 are additionally provided as the DC current sources for the switches M31 and M32.

To resonate the resonant circuit portion 100 at low frequencies, signals of opposite phases are supplied to the resonator by turning the switches M21/M22, and M24/M25 ON (H), and by turning the switches M23/M26 OFF (L). Signals of opposite phases pass respectively through the inductor including the coils L11 and L12 and through the inductor including the coils L21 and L22, so that a magnetic force acts to make the magnetic fluxes reinforce each other. Accordingly the resonant circuit portion 100 resonates at low frequencies.

To resonate the resonant circuit portion 100 at high frequencies, signals of the same phase are supplied to the resonator by turning the switches M21/M23, and M24/M26 ON (H), and by turning the switches M22/M25 OFF (L). Signals of the same phase respectively pass through the inductor including the coils L11/L12 and the inductor including the coils L21/L22 so that a magnetic force acts to make the magnetic fluxes cancel each other out. Accordingly the resonant circuit portion 100 resonates at high frequencies.

### Embodiment 7

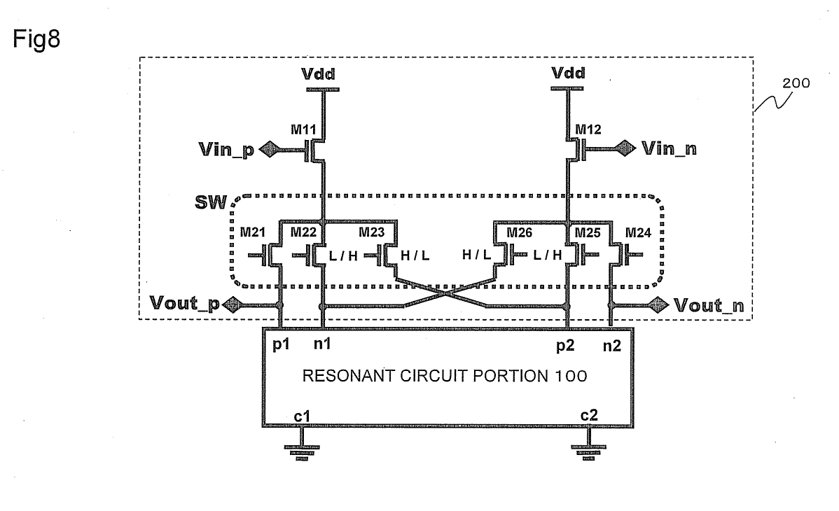

FIG. 8 shows a circuit of Embodiment 7 of the invention. The circuit of Embodiment 7 is an amplifier circuit including: a resonant circuit portion 100 that is similar to the one in Embodiment 2; and switches M21 to M26 configured to selectively switch signals to supply either signals of the same phase or signals of opposite phases to the coils L11 and L12, respectively, and to the coils L21 and L22, respectively. In addition, the switches M11/M12 operate as a common-drain amplifier circuit. The LC resonator is controlled in the same way as in the case of Embodiment 1, and is used mainly as a buffer circuit.

### Embodiment 8

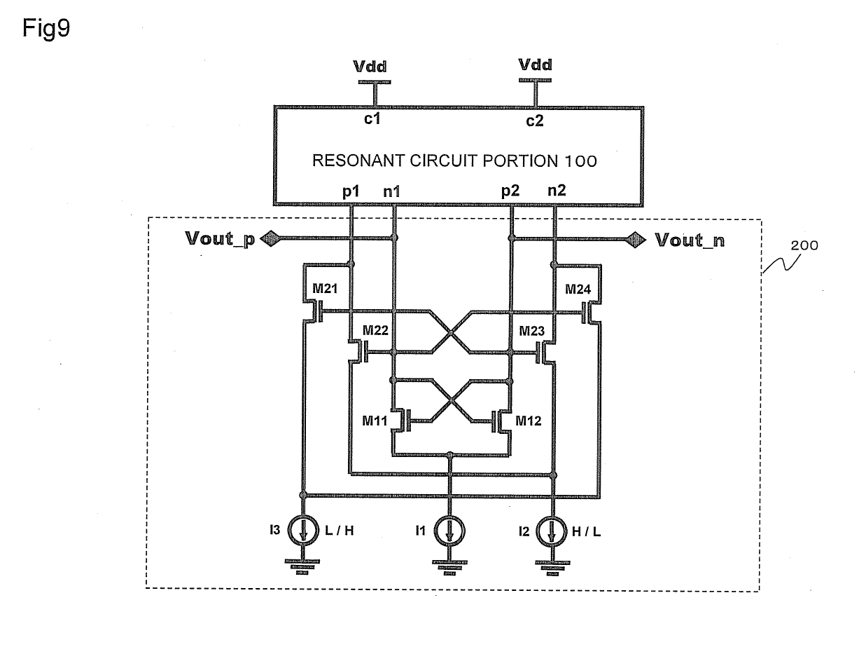

FIG. 9 shows a circuit of Embodiment 8 of the invention. The circuit of Embodiment 8 includes a resonant circuit portion 100 that is similar to the one in Embodiment 2 and an input-signal supplying portion 200 including: current sources I2/I3 and buffer elements M21 to M24 configured to selectively switch signals to supply either signals of the same phase or signals of opposite phases to the coils L11/L12, respectively, and to the coils L21/L22, respectively. In addition, a current source I1 is provided to supply current to M11/M12.

The voltage signals input into the gates of M21 to M24 appear as inverted signals at the drains of their respective transistors. Accordingly, by turning ON/OFF the current sources I2 and I3 selectively, the signal input into the gates of M22 and M23, and the signal input into the gates of M21 and M24 can switch the voltage signals at the drains of M11 and M12 to have either the same phase or opposite phases. Accordingly, the circuit of Embodiment 8 can change the frequency of the output signal as in the case of Embodiment 2.

### Other Embodiments

The capacitors C11, C12, C21 and C22 in Embodiments 1 to 7 may be replaced with variable capacitors (varactors). By this replacement, the frequency can be changed, so that the Q-factor of the coils L11 and L12 and that of the coils L21 and L22 degraded in the same-phase mode can be compensated by the coils L13 and L23 as well as the variable capacitors C11, C12, C21 and C22. Thus, while a broad variable frequency range is secured, the frequency band can be tuned finely. In addition, a high Q-factor can be secured even in the high-frequency mode, so that favorable gain characteristics and noise characteristics can be obtained.

If, in each Embodiment, the inductor including the coils L11/L12 and the inductor including the coils L21/L22 are used with the same phase, the output signals may be summed together to make the signal level higher than in the case of the output from either one alone.

In addition, the amplifier including the resonant circuit portion 100 can be formed not only as an FET but also as a bipolar one. Besides, the amplifier can be formed to be a PMOS one with reversed polarity.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor integrated circuit comprising:
a first coil and a second coil having a first coupling coefficient and being connected in parallel to each other;
a third coil connected in series to the first coil and the second coil;
a first capacitor connected in parallel to an end of the first coil and to an end of the third coil;
a second capacitor connected in parallel to an end of the second coil and to the end of the third coil;
a first input terminal connected to the end of the first coil and to an end of the first capacitor;
a second input terminal connected to the end of the second coil and to an end of the second capacitor; and
an input-signal supplying portion configured to supply input signals of opposite phases to the first input terminal and the second input terminal, respectively.

2. The semiconductor integrated circuit according to claim 1, wherein the input-signal supplying portion supplies input signals of the same phase to the first input terminal and to the second input terminal.

3. The semiconductor integrated circuit according to claim 1, wherein the input-signal supplying portion includes a switch configured to selectively switch input signals to input either signals of the same phase or signals of opposite phases to the first and the second input terminals, respectively.

4. The semiconductor integrated circuit according to claim 2, wherein the input-signal supplying portion includes a switch configured to selectively switch input signals to input either signals of the same phase or signals of opposite phases to the first and the second input terminals, respectively.

5. The semiconductor integrated circuit according to claim 1 further comprising:
a fourth coil and a fifth coil having the first coupling coefficient and being connected in parallel to each other;
a sixth coil connected in series to the fourth coil and to the fifth coil, the sixth coil and the third coil having a second coupling coefficient;
a third capacitor connected in parallel to an end of the fourth coil and to an end of the sixth coil;
a fourth capacitor connected in parallel to an end of the fifth coil and to the end of the sixth coil;
a third input terminal connected to the end of the fourth coil and to an end of the third capacitor;
a fourth input terminal connected to the end of the fifth coil and to an end of the fourth capacitor; and
an input-signal supplying portion configured to supply input signals of opposite phases to the first input terminal and the second input terminal, respectively, and to supply input signals of opposite phases to the third input terminal and the fourth input terminal, respectively.

6. The semiconductor integrated circuit according to claim 5, wherein
the input-signal supplying portion supplies input signals of the same phase to the first input terminal and the second input terminal, respectively,
the input-signal supplying portion supplies input signals of the same phase to the third input terminal and the fourth input terminal, respectively.

7. The semiconductor integrated circuit according to claim 6, wherein
the input signals supplied to the first input terminal and the second input terminal, respectively, have a opposite phase to the phase of the input signals supplied to the third input terminal and the fourth input terminal, respectively.

8. The semiconductor integrated circuit according to claim 5, wherein the input-signal supplying portion includes a switch configured to selectively switch input signals to input either signals of the same phase or signals of opposite phases to the first, the second, the third and the fourth input terminals, respectively.

9. The semiconductor integrated circuit according to claim 6, wherein the input-signal supplying portion includes a switch configured to selectively switch input signals to input either signals of the same phase or signals of opposite phases to the first and the second input terminals, respectively, and to the third and the fourth input terminals, respectively.

10. The semiconductor integrated circuit according to claim 7, wherein the input-signal supplying portion includes a switch configured to selectively switch input signals to input either signals of the same phase or signals of opposite phases to the first, the second, the third and the fourth input terminals, respectively.
